(19) United States
(12) Patent Application Publication
(10) Pub. No.: US 2026/0353898 A1
(43) Pub. Date: Nov. 5, 2026

(54) Light Emitting Display Apparatus

(71) Applicant: LG Display Co., Ltd., Seoul (KR)

(72) Inventor: HyeonHo Son, Paju-si (KR)

(21) Appl. No.: 19/659,746

(22) Filed: Apr. 27, 2026

(30) Foreign Application Priority Data
Apr. 30, 2025 (KR) 10-2025-0057244

(51) Int. Cl. H10H 29/855; G09G 3/32; G09G 3/3233; H10H 29/49

(52) U.S. Cl. CPC H10H 29/8552; G09G 3/32; G09G 3/3233; H10H 29/49; G09G 2300/0842; G09G 2320/068; G09G 2330/021

(57) ABSTRACT

A light emitting display apparatus according to one or more embodiments of the present disclosure comprises a substrate including a plurality of sub-pixels, and an optical member disposed on the substrate to include a plurality of optical elements overlapping each of the plurality of sub-pixels. Each of the plurality of sub-pixels comprises a pixel circuit connected to a data line and a gate line, and a light emitting part including a first light emitting device and a second light emitting device configured to emit light by a data current supplied from the pixel circuit. Each of the plurality of optical elements is configured to control traveling paths of light emitted from each of the first light emitting device and the second light emitting device in different directions.

### CROSS-REFERENCE TO RELATED APPLICATION

The present application claims priority to Republic of Korea Patent Application No. 10-2025-0057244, filed on Apr. 30, 2025, which is hereby incorporated by reference in its entirety.

### BACKGROUND

### Field

The present disclosure relates to a light emitting display apparatus.

### Description of Related Art

Display apparatuses are being widely used as a display screen of notebook computers, tablet computers, smartphones, portable display devices, and portable information devices or the like in addition to a display screen of television (TVs) and monitors.

Recently, research and development on light emitting display apparatuses using a light emitting device are being done. The light emitting display apparatuses have high image quality and high reliability, and thus, are attracting much attention as next-generation display devices.

### SUMMARY

The inventor of the present disclosure has performed various research and experiments for implementing light emitting display apparatuses capable of displaying a dual-view image through a plurality of pixels having a light emitting device. The inventor of the present disclosure has performed various research and experiments for implementing light emitting display apparatuses capable of limiting a display of contents which may degrade the driver’s concentration during operation of a vehicular apparatus (or a vehicle).

The inventor of the present disclosure has invented through various research and experiments, a light emitting display apparatus capable of displaying a dual-view image through a plurality of pixels having a light emitting device and has invented a light emitting display apparatus capable of controlling a viewing angle of an image based on a viewing angle mode.

An embodiment of the present disclosure is directed to providing a light emitting display apparatus capable of displaying a dual-view image through a plurality of pixels having a light emitting device.

Another embodiment of the present disclosure is directed to providing a light emitting display apparatus capable of switching a dual-view image without a decrease in resolution by using a plurality of pixels having a light emitting device.

Another embodiment of the present disclosure is directed to providing a light emitting display apparatus capable of implementing ESG (Environmental, Social, and Governance) performance through reduction of power consumption by displaying a dual-view image without a decrease in resolution.

Another embodiment of the present disclosure is directed to providing a light emitting display apparatus capable of controlling a viewing angle of an image based on a viewing angle mode by using a plurality of pixels having a light emitting device.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these and other advantages and in accordance with the purpose of the disclosure, as embodied and broadly described herein, in one or more embodiments, a light emitting display apparatus comprises a substrate including a plurality of sub-pixels, and an optical member disposed on the substrate to include a plurality of optical elements overlapping each of the plurality of sub-pixels. Each of the plurality of sub-pixels comprises a pixel circuit connected to a data line and a gate line, and a light emitting part including a first light emitting device and a second light emitting device configured to emit light by a data current supplied from the pixel circuit. Each of the plurality of optical elements is configured to control traveling paths of light emitted from each of the first light emitting device and the second light emitting device in different directions.

Specific details according to various embodiments of the present disclosure, other than the means for solving the above-described problems, are included in the following description and accompanying drawings.

One or more embodiments of the present disclosure may provide a light emitting display apparatus capable of displaying a dual-view image through a plurality of pixels having a light emitting device.

One or more embodiments of the present disclosure may provide a light emitting display apparatus capable of switching a dual-view image without a decrease in resolution by using a plurality of pixels.

One or more embodiments of the present disclosure may implement ESG (Environmental, Social, and Governance) performance through reduction of power consumption by displaying a dual-view image without a decrease in resolution.

One or more embodiments of the present disclosure may provide a light emitting display apparatus capable of controlling a viewing angle of an image based on a viewing angle mode by using a plurality of pixels having a light emitting device.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further embodiments and advantages are discussed below in conjunction with embodiment of the disclosure.

It is to be understood that both the foregoing description and the following description of the present disclosure are exemplary and explanatory and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this disclosure, illustrate aspects and embodiments of the present disclosure and together with the description serve to explain principles of the disclosure. However, the technical features of embodiments of the present disclosure are not limited to those shown in the specific drawings, and the features disclosed in each drawing may be combined to form a new embodiment.

FIG. 1 is a view illustrating a light emitting display apparatus according to one or more embodiments of the present disclosure.

FIG. 2 is an equivalent circuit diagram illustrating one sub-pixel illustrated in FIG. 1 and a cross-sectional view illustrating a light emitting device.

FIG. 3 is a cross-sectional view taken along line I-I’ illustrated in FIG. 1.

FIG. 4 is a view illustrating a method of driving a sub-pixel according to a first image mode of a light emitting display apparatus according to one or more embodiments of the present disclosure.

FIG. 5 is a view illustrating a path of light emitted from a light emitting part according to the method of driving a sub-pixel illustrated in FIG. 4.

FIG. 6 is a view illustrating a method of driving a sub-pixel for an N-th frame period in a second image mode of a light emitting display apparatus according to one or more embodiments of the present disclosure.

FIG. 7 is a view illustrating a path of light emitted from a light emitting part according to the method of driving a sub-pixel illustrated in FIG. 6.

FIG. 8 is a view illustrating a method of driving a sub-pixel for an (N+1)-th frame period in a second image mode of a light emitting display apparatus according to one or more embodiments of the present disclosure.

FIG. 9 is a view illustrating a path of light emitted from a light emitting part according to the method of driving a sub-pixel illustrated in FIG. 8.

FIG. 10 is another cross-sectional view taken along line I-I’ illustrated in FIG. 1.

FIG. 11 is a view illustrating a path of light emitted from a light emitting part according to the method of driving a sub-pixel illustrated in FIG. 4.

FIG. 12 is a view illustrating a path of light emitted from a light emitting part according to the method of driving a sub-pixel illustrated in FIG. 6.

FIG. 13 is a view illustrating a path of light emitted from a light emitting part according to the method of driving a sub-pixel illustrated in FIG. 8.

FIG. 14 is another cross-sectional view taken along line I-I’ illustrated in FIG. 1.

FIG. 15 is an equivalent circuit diagram illustrating one sub-pixel illustrated in FIG. 1.

Throughout the drawings and the detailed description, unless otherwise described, the same drawing reference numerals should be understood to refer to the same elements, features, and structures. The sizes, lengths, and thicknesses of layers, regions, and elements, and depiction thereof may be exaggerated for clarity, illustration, and/or convenience.

### DETAILED DESCRIPTION

A shape, a size, a ratio, an angle, and a number disclosed in the drawings for describing embodiments of the present disclosure are merely examples. Thus, the present disclosure is not limited to the illustrated details. Like reference numerals refer to like elements throughout, unless otherwise specified. In the following description, where the detailed description of the relevant known function or configuration may unnecessarily obscure aspects or features of the present disclosure, the detailed description of such known function or configuration may be omitted.

In a situation where terms like “comprise,” “have,” and “include” are used in describing embodiments of the present disclosure, another part may be added unless a more specific term like “only” is used. The terms of a singular form can include plural forms, and vice versa, unless referred to the contrary.

In construing an element, the element should be construed as including an error range although there is no explicit description.

In describing a position relationship, for example, where a position relation between two parts is described as “on”, “over”, “under”, “next”, and “adjacent to” or the like, one or more other parts may be located between the two parts unless a more limiting term, such as “immediate(ly)”, “direct(ly)”, or “close(ly)”, is used.

For the expression that an element is “connected”, “coupled”, “contact”, or “attach” to another element, the element may not only be directly connected, coupled, or contacted to another element, but also be indirectly connected, coupled, contacted, or attached to another element with one or more intervening elements interposed between the elements, unless otherwise specified.

For the expression that an element “contacts” or “overlaps” with another element, the element can not only directly contact, overlap, or the like with another element, but also indirectly contact or overlap with another element with one or more intervening elements disposed or interposed between the elements, unless otherwise specified.

Such terms as “a first direction”, “a second direction”, “a third direction”, “X-axis direction”, “Y-axis direction”, and “Z-axis direction” should not be construed by a geometric relation only of a mutual vertical relation and may have broader directionality within the range that elements of the present disclosure may act functionally.

Features of various embodiments of the present disclosure may be partially or wholly coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, example embodiments of the present disclosure will be described in detail with reference to the accompanying drawings. For convenience of description, a scale of each of elements illustrated in the accompanying drawings may differ from an actual scale, dimension, size, and thickness, and thus, embodiments of the present disclosure are not limited to a scale, dimension, size, and thickness illustrated in the drawings.

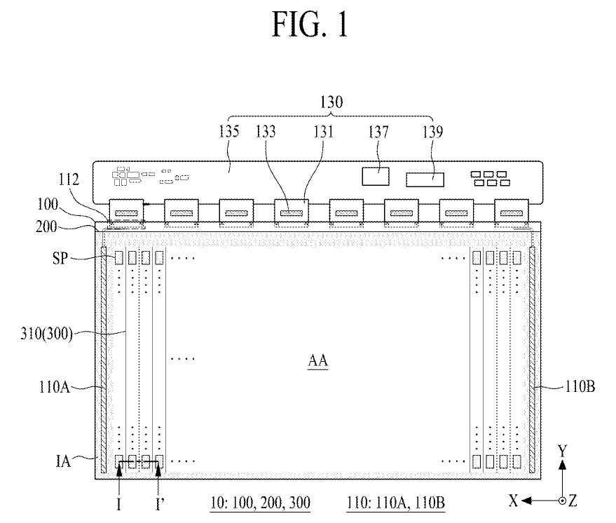

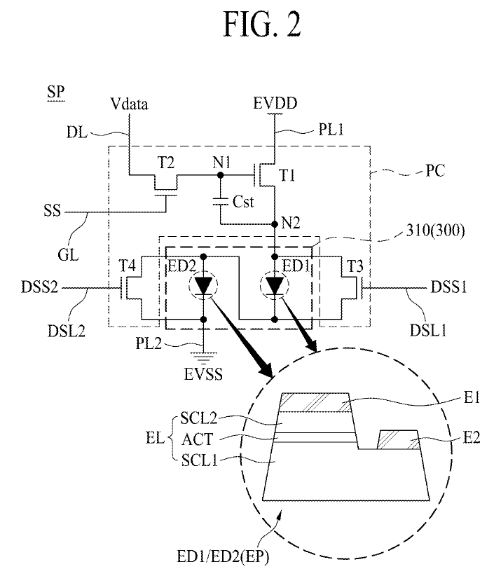

FIG. 1 is a view illustrating a light emitting display apparatus according to one or more embodiments of the present disclosure. FIG. 2 is an equivalent circuit diagram illustrating one sub-pixel illustrated in FIG. 1 and a cross-sectional view illustrating a light emitting device.

Referring to FIGS. 1 and 2, a light emitting display apparatus according to one or more embodiments of the present disclosure may include a substrate 100 and an optical member 300.

The substrate 100 may be a first substrate, a thin-film transistor array substrate, or a pixel array substrate. The substrate 100 may be made of a glass or plastic material. The substrate 100 according to one or more embodiments includes a display area AA and a non-display area IA.

The display area AA may be defined as an area for displaying an image. The non-display area IA may be a peripheral portion outside the display area AA and cannot display an image unlike the display area AA, and moreover, the non-display area IA may be defined as an area where lines and circuits or the like for driving the plurality of sub-pixels SP are disposed.

The substrate 100 according to one or more embodiments may include a plurality of sub-pixels SP. Moreover, the non-display area IA may be defined as an area where lines and circuits or the like for driving the plurality of sub-pixels SP are disposed.

The plurality of sub-pixels SP may be arranged along a first direction X and a second direction Y intersecting the first direction X, respectively.

Each of the plurality of sub-pixels SP may be defined as a minimum unit from which actual light is emitted. Three or more adjacent sub-pixels SP among the plurality of sub-pixels SP may configure one unit pixel for color display. For example, one unit pixel may include one or more red sub-pixels, one or more green sub-pixels, and one or more blue sub-pixels, but is not limited thereto.

Each of the plurality of sub-pixels SP may be disposed in a sub-pixel area. The sub-pixel area may be defined by an intersection of a plurality of gate lines GL and a plurality of data lines DL. Each of the plurality of sub-pixels SP is disposed in the sub-pixel area and may be configured to be electrically connected to the gate line GL and the data line DL. Each of the plurality of sub-pixels SP may be configured to be additionally connected to a first power line PL1 and a second power line PL2 disposed on the substrate 100.

Each of the plurality of gate lines GL extends long along a first direction X (or an X-axis direction) of the substrate 100 and may be spaced apart at a constant interval along a second direction Y (or a Y-axis direction). Each of the plurality of gate lines GL may be shared by sub-pixels disposed along the first direction X among the plurality of sub-pixels SP. Each of the plurality of gate lines GL may be configured to supply (or transmit) a scan signal SS to the plurality of sub-pixels SP.

The plurality of data lines DL are spaced apart at a constant interval along the first direction X of the substrate 100 and may extend long along the second direction Y of the substrate 100. Each of the plurality of data lines DL may be shared by sub-pixels disposed along the second direction Y among the plurality of sub-pixels SP. Each of the plurality of data lines DL may be configured to supply (or transmit) a data signal Vdata to the plurality of sub-pixels SP.

Each of a plurality of first power lines PL1 may be disposed on the substrate 100 to be parallel to the data line DL, but is not limited thereto. Each of the plurality of first power lines PL1 may be configured to supply (or transmit) a pixel driving voltage (or a high-potential voltage) EVDD to the plurality of sub-pixels SP.

Each of a plurality of second power lines PL2 may be disposed on the substrate 100 to be parallel to the data line DL, but is not limited thereto. Each of the plurality of second power lines PL2 may be configured to supply (or transmit) a pixel common voltage (or a low-potential voltage) EVSS to the plurality of sub-pixels SP.

Each of the plurality of sub-pixels SP according to one or more embodiments of the present disclosure may include a light emitting part EP and a pixel circuit PC.

The light emitting part EP may include a plurality of light emitting devices ED1 and ED2 connected in series, but is not limited thereto. For example, each of the plurality of light emitting devices ED1 and ED2 may be a light emitting diode device, a light emitting diode chip, a micro light emitting device, a micro light emitting diode, or a micro light emitting diode chip. For example, each of the plurality of light emitting devices ED1 and ED2 may have a scale of 1 μm to 100 μm, but is not limited thereto.

The light emitting part EP according to one or more embodiments may include first and second light emitting devices ED1 and ED2 connected in series.

The first and second light emitting devices ED1 and ED2 may be electrically connected in series between the pixel circuit PC and the second power line PL2. For example, the first light emitting device ED1 may be a first viewing angle light emitting device (or a light emitting device for a second viewing angle), and the second light emitting device ED2 may be a second viewing angle light emitting device (or a light emitting device for a second viewing angle), but is not limited thereto. For example, the first light emitting device ED1 may be a light emitting device for a first image, and the second light emitting device ED2 may be a light emitting device for a second image, but is not limited thereto.

According to one or more embodiments, a first electrode (or an anode electrode) of the first light emitting device ED1 may be electrically connected to the pixel circuit PC, and a second electrode (or a cathode electrode) of the first light emitting device ED1 may be electrically connected to a first electrode (or an anode electrode) of the second light emitting device ED2. In addition, a second electrode (or a cathode electrode) of the second light emitting device ED2 may be electrically connected to the second power line PL2.

Each of the plurality of light emitting devices (or first and second light emitting devices) ED1 and ED2 of the light emitting part EP may include a light emitting layer EL, a first electrode (or an anode terminal) E1, and a second electrode (or a cathode terminal) E2. For example, each of the plurality of light emitting devices (or first and second light emitting devices) ED1 and ED2 may have a lateral structure, but is not limited thereto.

The light emitting layer EL may emit light based on the recombination of electrons and holes depending on a current flowing between the first electrode E1 and the second electrode E2. The light emitting layer EL according to one or more embodiments may include a first semiconductor layer SCL1, an active layer ACT, and a second semiconductor layer SCL2.

The first semiconductor layer SCL1 may be configured to provide electrons to the active layer ACT. The first semiconductor layer SCL1 according to one or more embodiments may be made of an n-GaN-based semiconductor material. Examples of the n-GaN-based semiconductor material may include GaN, AlGaN, InGaN, or AlInGaN, or the like, but are not limited thereto. For example, impurities used for doping of the first semiconductor layer SCL1 may include silicon (Si), germanium (Ge), selenium (Se), tellurium (Te), or carbon (C), or the like, but are not limited thereto.

The active layer ACT may be disposed on one side of the first semiconductor layer SCL1. The active layer ACT may have a multi-quantum well structure which includes a well layer and a barrier layer which is a higher bandgap than the well layer. For example, the active layer ACT may have a multi-quantum well structure of InGaN/GaN or the like.

The second semiconductor layer SCL2 may be disposed on the active layer ACT and may be configured to provide holes to the active layer ACT. The second semiconductor layer SCL2 according to one or more embodiments may be made of a p-GaN-based semiconductor material. Examples of the p-GaN-based semiconductor material may include GaN, AlGaN, InGaN, or AlInGaN, or the like. For example, impurities used for doping of the second semiconductor layer SCL2 may include magnesium (Mg), zinc (Zn), or beryllium (Be), or the like, but are not limited thereto.

The first electrode E1 may be disposed on the second semiconductor layer SCL2. The second electrode E2 may be disposed on the other side of the first semiconductor layer SCL1 so as to be electrically separated (or disconnected) from the active layer ACT and the second semiconductor layer SCL2.

In FIG. 2, the plurality of light emitting devices (or first and second light emitting devices) ED1 and ED2 are described as including the lateral structure, but are not limited thereto. For example, the plurality of light emitting devices (or first and second light emitting devices) ED1 and ED2 may have a vertical structure or a flip-chip structure.

The pixel circuit PC may be configured to control a current flowing to the light emitting part EP based on a scan signal SS which is supplied through a gate line GL and a data signal which is supplied through a data line DL.

The pixel circuit PC may be configured to be electrically connected to the gate line GL, the data line DL, and first and second device selection lines DSL1 and DSL2.

The first device selection line (or a first selection line) DSL1 may be configured to supply (or transmit) a first device selection signal (or a first selection signal) DSS1 to the pixel circuit PC. The second device selection line (or a second selection line) DSL2 may be configured to supply (or transmit) a second device selection signal (or a second selection signal) DSS2 to the pixel circuit PC. For example, the first device selection signal DSS1 and the second device selection signal DSS2 may be a same as or different from each other based on a driving mode (or an operation mode or a viewing angle mode).

Each of the first device selection line DSL1 and the second device selection line DSL2 may be disposed parallel to the data line DL. For example, the first device selection lines DSL1 disposed at each of the plurality of sub-pixels SP may be connected to each other. The second device selection lines DSL2 disposed at each of the plurality of sub-pixels SP may be connected to each other.

The pixel circuit PC may include first and second nodes N1 and N2, first to fourth thin-film transistors T1, T2, T3, and T4, and a capacitor Cst.

The first to fourth thin-film transistors T1, T2, T3, and T4 may be configured of a same type among P-type and N-type thin-film transistors, or may be configured of different types. One or more of the first to fourth thin-film transistors T1, T2, T3, and T4 may include a semiconductor layer made of a same or different materials among an amorphous silicon, a polycrystalline silicon, a low-temperature polycrystalline silicon, an oxide, and an organic material. In the following description, it is assumed that each of the first to fourth thin-film transistors T1, T2, T3, and T4 is an N-type thin-film transistor.

The first thin-film transistor (or a driving thin-film transistor) T1 may be connected to the first node N1 and the second node N2, and may be configured to control a current flowing from the first power line PL1 to the second node N2 based on a voltage level of the first node N1. For example, the first thin-film transistor T1 may include a gate electrode connected to the first node N1, a source electrode connected to the second node N2, and a drain electrode connected to the first power line PL1. The source electrode of the first thin-film transistor T1 may be electrically connected to the light emitting part EP through the second node N2. For example, the source electrode of the first thin-film transistor T1 may be electrically connected to the first electrode E1 of the first light emitting device ED1 of the light emitting part EP through the second node N2. For example, the first light emitting device ED1 and the second light emitting device ED2 may be electrically connected in series between the first thin-film transistor T1 and the second power line PL2. For example, the first light emitting device ED1 and the second light emitting device ED2 may be electrically connected in series between the second node N2 and the second power line PL2.

The second thin-film transistor (or a switching thin-film transistor) T2 is turned-on based on a scan signal SS applied from a gate line GL (or a scan line), and may be configured to be electrically connected between the data line DL and the first node N1. The second thin-film transistor T2 may supply (or transmit) a data signal Vdata, which is supplied through the data line DL, to the first node N1 based on the scan signal SS. For example, the second thin-film transistor T2 may include a gate electrode connected to the gate line GL, a source electrode (or a drain electrode) connected to the data line DL, and a drain electrode (or a source electrode) connected to the first node N1.

The third thin-film transistor (or a first device selection thin-film transistor or a first path control thin-film transistor or a first selection thin-film transistor) T3 may be configured to selectively cause the first light emitting device ED1 to emit light based on the driving mode (or the viewing angle mode). The third thin-film transistor T3 may be turned-on based on the first device selection signal DSS1 and may be configured to block a current flowing to the first light emitting device ED1. The third thin-film transistor T3 may be electrically connected in parallel with the first light emitting device ED1. For example, the third thin-film transistor T3 may be connected to both ends of the first light emitting device ED1 and may be turned-on based on the first device selection signal DSS1.

The third thin-film transistor T3 may be configured to block or bypass a current applied from the first thin-film transistor T1 to the first light emitting device ED1 based on the first device selection signal DSS1. For example, the first light emitting device ED1 may emit light by a data current output from the first thin-film transistor T1 during a turn-off period of the third thin-film transistor T3. During a turn-on period of the third thin-film transistor T3, the data current output from the first thin-film transistor T1 may bypass the first light emitting device ED1 and flow toward the second light emitting device ED2 through the third thin-film transistor T3. For example, the third thin-film transistor T3 may bypass the current applied to the first light emitting device ED1 in a second mode (or a second viewing angle mode or a second operation mode).

The third thin-film transistor T3 may include a gate electrode for receiving the first device selection signal DSS1, a source electrode (or a drain electrode) connected to the second node N2 (or the source electrode of the first thin-film transistor T1 or the first electrode E1 of the first light emitting device ED1), and a drain electrode (or a source electrode) connected to the second electrode E2 of the first light emitting device ED1 (or the first electrode E1 of the second light emitting device ED2). The first device selection signal DSS1 may include a gate-on voltage period and a gate-off voltage period. The first light emitting device ED1 may not emit light during the gate-on voltage period of the first device selection signal DSS1, and may emit light during the gate-off voltage period of the first device selection signal DSS1.

The fourth thin-film transistor (or a second device selection thin-film transistor or a second path control thin-film transistor or a second selection thin-film transistor) T4 may be configured to selectively cause the second light emitting device ED2 to emit light based on the mode (or the viewing angle mode). The fourth thin-film transistor T4 is turned-on based on the second device selection signal DSS2 and may be configured to block a current flowing to the second light emitting device ED2. The fourth thin-film transistor T4 may be electrically connected in parallel with the second light emitting device ED2. The fourth thin-film transistor T4 may be connected to both ends of the second light emitting device ED2 and may be turned-on based on the second device selection signal DSS2.

The fourth thin-film transistor T4 may be configured to block or bypass a current applied to the second light emitting device ED2 through the first light emitting device ED1 or the third thin-film transistor T3. For example, the second light emitting device ED2 may emit light by the data current applied through the first light emitting device ED1 or the third thin-film transistor T3 during a turn-off period of the fourth thin-film transistor T4. During a turn-on period of the fourth thin-film transistor T4, the data current output from the first light emitting device ED1 or the third thin-film transistor T3 may bypass the second light emitting device ED2 and flow to the second power line PL2 through the fourth thin-film transistor T4. For example, the fourth thin-film transistor T4 may be configured to bypass a current applied to the second light emitting device ED2 in a first mode (or a first viewing angle mode or a first operation mode).

The fourth thin-film transistor T4 may include a gate electrode for receiving the second device selection signal DSS2, a source electrode (or a drain electrode) connected to the second electrode E2 of the first light emitting device ED1, and a drain electrode (or a source electrode) connected to the second power line PL2 (or the second electrode E2 of the second light emitting device ED2). The second device selection signal DSS2 may include a gate-on voltage period and a gate-off voltage period. The second light emitting device ED2 may not emit light during the gate-on voltage period of the second device selection signal DSS2, and may emit light during the gate-off voltage period of the second device selection signal DSS2.

According to one or more embodiments, the current flowing from the first thin-film transistor T1 to the light emitting part EP may flow through one or more of the first and second light emitting devices ED1 and ED2. In the first mode (or the first viewing angle mode), the current flowing from the first thin-film transistor T1 to the light emitting part EP may flow through both the first and second light emitting devices ED1 and ED2. In the second mode (or the second viewing angle mode), the current flowing from the first thin-film transistor T1 to the light emitting part EP may flow through any one of the first and second light emitting devices ED1 and ED2 in units of a frame period. In the second mode (or the second viewing angle mode), the current flowing from the first thin-film transistor T1 to the light emitting part EP during an N-th (N is a natural number) frame period flows through only the first light emitting device ED1, and the current flowing from the first thin-film transistor T1 to the light emitting part EP during an (N+1)-th frame period may flow through only the second light emitting device ED2. An image of the N-th frame period may be a content image that is different or distinct from an image of the (N+1)-th frame period. Accordingly, the current flowing to the light emitting part EP during the N-th frame period and the current flowing to the light emitting part EP during the (N+1)-th frame period may correspond to different images. For example, the content image may include one or more of entertainment images, media images, and vehicle navigation images, but is not limited thereto.

The light emitting display apparatus according to one or more embodiments of the present disclosure may further include an opposite substrate 200. The opposite substrate 200 may be configured to cover the substrate 100. The opposite substrate 200 may be a second substrate, a protective substrate, or an encapsulation substrate. The opposite substrate 200 may be opposite-bonded to the substrate 100 by a transparent adhesive member. The substrate 100 and the opposite substrate 200 may configure a display panel 10.

The light emitting display apparatus according to one or more embodiments of the present disclosure may further include a gate driving circuit 110 and a panel driving circuit part 130.

The gate driving circuit 110 may be configured to supply the scan signal SS in a predetermined order to the plurality of gate lines GL based on a gate control signal supplied from the panel driving circuit part 130. The gate driving circuit 110 may be formed (or configured) in the non-display area IA of the substrate 100. The gate driving circuit 110 may include a first gate driving circuit 110A and a second gate driving circuit 110B.

The first gate driving circuit 110A may be disposed at a first non-display area (or a left non-display area) of the display area AA to be electrically connected to one end of each of the plurality of gate lines GL. The second gate driving circuit 110B may be disposed at a second non-display area (or a right non-display area) to be electrically connected to the other end of each of the plurality of gate lines GL. The gate driving circuit 110 (or the first and second gate driving circuits 110A and 110B) may be directly formed or implemented at the non-display area IA of the substrate 100 by a manufacturing process of a thin-film transistor of the sub-pixels SP based on a GIP (gate in panel) method. For example, the gate driving circuit 110 (or the first and second gate driving circuits 110A and 110B) may be a gate built-in circuit or a gate shift register circuit.

The panel driving circuit part 130 may be connected to a pad part 112 provided at the non-display area IA at one side of the substrate 100 and may be configured to display an image corresponding to image data supplied from a display driving system on the display area AA.

The panel driving circuit part 130 according to one or more embodiments may be configured to include a plurality of flexible circuit films 131, a plurality of data driving integrated circuits 133, a printed circuit board 135, a timing control part 137, and a power circuit 139.

Each of the plurality of flexible circuit films 131 may be attached to the pad part 112 of the substrate 100 by a film attachment process.

Each of the plurality of data driving integrated circuits 133 may be individually mounted on each of the plurality of flexible circuit films 131. The data driving integrated circuit 133 may receive sub-pixel data and a data control signal provided from the timing control part 137, may convert sub-pixel data into an analog-type data signal (or voltage) for each sub-pixel based on the data control signal, and may supply analog sub-pixel data signals to corresponding data lines DL.

The printed circuit board 135 may be connected to the plurality of flexible circuit films 131. The printed circuit board 135 may support the timing control part 137 and the power circuit 139 and may serve to transmit signals and power between the components of the panel driving circuit part 130.

The timing control part 137 may be mounted on the printed circuit board 135 and may receive image data and a timing synchronization signal provided from the display driving system through a user connector provided on the printed circuit board 135. The timing control part 137 may generate the sub-pixel data by aligning the image data to be suitable for an arrangement structure of the sub-pixels SP of the display area AA based on the timing synchronization signal, and may provide the generated sub-pixel data to the data driving integrated circuit 133.

The timing control part 137 may be configured to generate each of the data control signal and the gate control signal based on the timing synchronization signal to control driving timings of each of the plurality of data driving integrated circuits 133 and the gate driving circuit 110.

The timing control part 137 may be configured to generate first and second device selection signals DSS1 and DSS2 for selectively emitting light from one or more of the first and second light emitting devices ED1 and ED2 disposed at each of the plurality of sub-pixels SP and supply to the first and second device selection lines DSL1 and DSL2. For example, the timing control part 137 may be configured to generate the first and second device selection signals DSS1 and DSS2 based on the driving mode (or viewing angle mode) and supply to the first and second device selection lines DSL1 and DSL2.

The driving mode according to one or more embodiments may include first and second image modes.

The first image mode may be a mode for displaying a dual-view image on the display panel 10 through simultaneous light emission of the first and second light emitting devices ED1 and ED2. For example, the timing control part 137 may be configured to generate the first and second device selection signals DSS1 and DSS2 having a first logic state (or a gate-off voltage) for simultaneously emitting light from the first light emitting device ED1 and the second light emitting device ED2 to emit light based on the first image mode.

The second image mode may be a mode for displaying individual (or separate) images on the display panel 10 through alternating driving (or alternating light emission) of the first light emitting device ED1 and the second light emitting device ED2. In the second image mode, the first light emitting device ED1 and the second light emitting device ED2 may alternately emit light in units of a frame period by different data currents corresponding to individual images. In the second image mode, an image of the N-th frame period may be a content image that is different or distinct from an image of the (N+1)-th frame period. Based on the second image mode, the timing control part 137 may be configured to generate the first device selection signal DSS1 having the first logic state (or the gate-off voltage) and the second device selection signal DSS2 having a second logic state (or a gate-on voltage) during the N-th frame period, and generate the first device selection signal DSS1 having the second logic state and the second device selection signal DSS2 having the first logic state during the (N+1)-th frame period.

The driving mode (or viewing angle mode) according to one or more other embodiments may include a first viewing angle mode and a second viewing angle mode.

The first viewing angle mode may be a wide viewing angle mode or a general viewing mode (or a general watching mode). The first viewing angle mode may be a mode for displaying a general view image on the display panel 10 through simultaneous light emission of the first and second light emitting devices ED1 and ED2. For example, the timing control part 137 may be configured to generate the first and second device selection signals DSS1 and DSS2 having the first logic state (or the gate-off voltage) for simultaneously emitting light from the first light emitting device ED1 and the second light emitting device ED2 based on the first viewing angle mode.

The second viewing angle mode according to one or more embodiments may be a narrow viewing angle mode or a privacy mode (or a personal security mode). The second viewing angle mode may be a mode for displaying a personal security image (or an individual image or a separate image) different from an image displayed in the first viewing angle mode on the display panel 10 through light emission of only one of the first and second light emitting devices ED1 and ED2. For example, the second viewing angle mode may be a mode for displaying an individual (or separate or personal security) image on the display panel 10 through light emission of only the first light emitting device ED1 among the first and second light emitting devices ED1 and ED2. In the second viewing angle mode, the second light emitting device ED2 may not emit light. For example, the timing control part 137 may be configured to generate the first device selection signal DSS1 having the first logic state and the second device selection signal DSS2 having the second logic state based on the second viewing angle mode according to one or more embodiments.

The second viewing angle mode according to one or more other embodiments may be a mode for alternately displaying a personal security image and a personal non-security image on the display panel 10 in units of a frame period through alternating driving (or alternating light emission) of the first light emitting device ED1 and the second light emitting device ED2. In the second viewing angle mode according to one or more other embodiments, the first light emitting device ED1 and the second light emitting device ED2 may display different images by alternately emitting light in units of a frame period by different data currents. In the second viewing angle mode, an image of the N-th frame period may be the personal security image and may be realized with a narrow viewing angle, and an image of the (N+1)-th frame period may be the personal non-security image and may be realized with the narrow viewing angle. Based on the second viewing angle mode according to one or more other embodiments, the timing control part 137 may be configured to generate the first device selection signal DSS1 having the first logic state and the second device selection signal DSS2 having the second logic state during the N-th frame period, and generate the first device selection signal DSS1 having the second logic state and the second device selection signal DSS2 having the first logic state during the (N+1)-th frame period.

The power circuit 139 may be mounted on the printed circuit board 135 and may be configured to generate various voltages necessary for displaying an image in the display area AA using input power input from an outside and configured to supply to a corresponding component.

The optical member 300 may be disposed on the substrate 100 to include a plurality of optical elements 310 overlapping each of the plurality of sub-pixels SP. For example, the optical member 300 may be disposed between the light emitting part EP and the opposite substrate 200, but is not limited thereto. For example, the optical member 300 may be attached to the opposite substrate 200 by using an adhesive member. In this case, the opposite substrate 200 may be disposed between the optical member 300 and the substrate 100.

The optical member 300 or the plurality of optical elements 310 may be configured to control traveling paths of light emitted from each of the plurality of sub-pixels SP in different directions. The optical member 300 or the plurality of optical elements 310 may be configured to control the traveling paths of light emitted from each of the plurality of sub-pixels SP in different directions based on the driving mode (or the viewing angle mode) of the light emitting display apparatus (or the display panel 10). The first and second light emitting devices ED1 and ED2 disposed in one sub-pixel SP may overlap a corresponding one of the plurality of optical elements 310. Accordingly, the optical member 300 or each of the plurality of optical elements 310 may be configured to control traveling paths of light emitted from each of the first and second light emitting devices ED1 and ED2 disposed in one sub-pixel SP in different directions.

Each of the plurality of optical elements 310 according to one or more embodiments may include a convex lens shape or a lenticular lens, but is not limited thereto. Accordingly, the optical member 300 may include a lenticular lens member or a lenticular lens film.

Each of the plurality of optical elements 310 may be arranged in parallel to each other along the first direction X and may extend long along the second direction Y. Each of the plurality of optical elements 310 may be formed parallel to the data line DL to have a preset width.

According to one or more embodiments, one optical element 310 may be disposed to cover the first and second light emitting devices ED1 and ED2 which are disposed at one sub-pixel SP. Accordingly, light emitted from each of the first and second light emitting devices ED1 and ED2 disposed at one sub-pixel SP may be emitted to the outside through paths in different directions by the optical element (or lenticular lens) 310. For example, light emitted from each of the first and second light emitting devices ED1 and ED2 disposed at one sub-pixel SP may realize different viewing angles by one optical element 310.

As described above, the light emitting display apparatus according to one or more embodiments of the present disclosure may display a dual-view image or switch (or convert) and display a general image into a dual-view image without a decrease in resolution based on selective light emission of the first and second light emitting devices ED1 and ED2 disposed at each of the plurality of sub-pixels SP and the control of light paths (or viewing angles) by the optical element 310, and may control a viewing angle of an image based on the viewing angle mode.

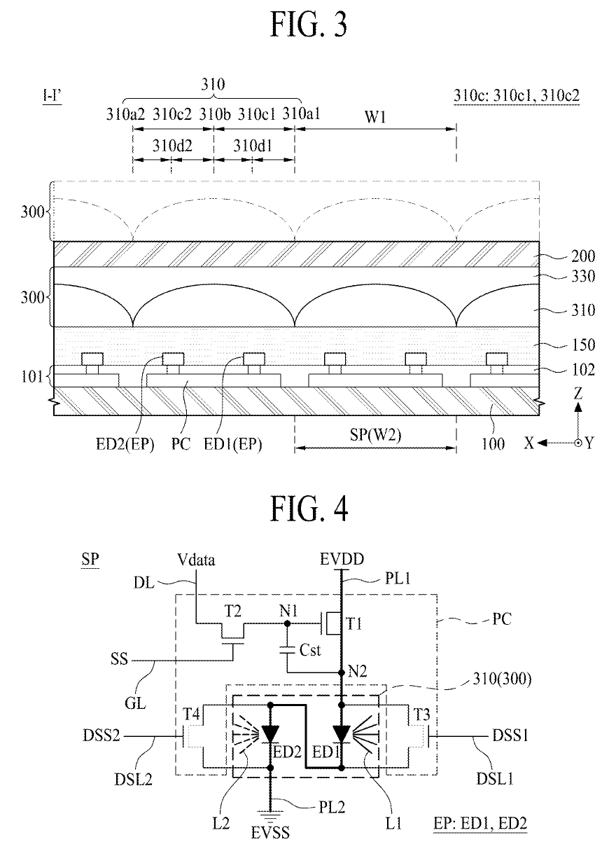

FIG. 3 is a cross-sectional view taken along line I-I’ illustrated in FIG. 1. FIG. 3 is a view for explaining an optical member according to one or more embodiments of the present disclosure.

Referring to FIGS. 1 - 3, the light emitting display apparatus according to one or more embodiments of the present disclosure may include a pixel circuit layer 101, an optical member 300, and an opposite substrate 200 which are disposed on a substrate 100.

The pixel circuit layer 101 may include lines GL, DL, PL1, PL2, DSL1, and DSL2 disposed on the substrate 100, and a pixel circuit PC connected to the lines GL, DL, PL1, PL2, DSL1, and DSL2. The pixel circuit PC may be covered by a planarization layer 102. The planarization layer 102 may be formed to provide a flat surface on an upper portion of the pixel circuit PC.

Each of first and second light emitting devices ED1 and ED2 disposed at each of the plurality of sub-pixels SP may be disposed on the planarization layer 102 and may be electrically connected to the pixel circuit PC through a contact hole formed at the planarization layer 102. The first and second light emitting devices ED1 and ED2 disposed at each of the plurality of sub-pixels SP may also be covered by a second planarization layer.

The optical member 300 may be disposed on the pixel circuit layer 101. For example, the optical member 300 may be attached to the pixel circuit layer 101 by using an adhesive member 150. The first and second light emitting devices ED1 and ED2 disposed at each of the plurality of sub-pixels SP may be covered or surrounded by the adhesive member 150.

The optical member 300 may include a plurality of optical elements 310. A width W1 of each of the plurality of optical elements 310 may have a size corresponding to a width W2 of one sub-pixel SP. The width W1 of one optical element 310 may correspond to or be a same as the width W2 of the sub-pixel SP. The width W1 of one optical element 310 may be a same as a pitch of the plurality of sub-pixels SP. Each of the plurality of optical elements 310 may include a lenticular lens having a width W1 parallel to the first direction X and a length parallel to the second direction Y, but is not limited thereto.

Each of the plurality of optical elements (or lenticular lenses) 310 may include a first end 310a1, a second end 310a2, a center portion 310b, and a curved portion 310c.

The first end 310a1 may be one end of each of the plurality of optical elements (or lenticular lenses) 310. The second end 310a2 may be the other end of each of the plurality of optical elements (or lenticular lenses) 310, which is opposite to the first end 310a1. The first end 310a1 and the second end 310a2 may be parallel to each other and may be parallel to the data line DL.

The center portion 310b may include a middle portion between the first end 310a1 and the second end 310a2. The first end 310a1 and the second end 310a2 may be parallel to each other with the center portion 310b therebetween. For example, each of the plurality of optical elements (or lenticular lenses) 310 may have a symmetrical structure (or a left-right symmetrical structure) with respect to the center portion 310b.

The curved portion 310c may include a curved shape having a preset curvature between the first end 310a1 and the second end 310a2. The curved portion 310c may be formed in a curved shape having one curvature. Accordingly, each of the plurality of optical elements (or lenticular lenses) 310 may include a curved shape having one curvature. The curved shape of the curved portion 310c may have a maximum slope that decreases from each of the first end 310a1 and the second end 310a2 toward the center portion 310b.

The curved portion 310c according to one or more embodiments may include a first curved portion 310c1 and a second curved portion 310c2.

The first curved portion 310c1 may include a first half portion of the curved portion 310c. The first curved portion 310c1 may include a portion (or a first half portion) between the center portion 310b and the first end 310a1. The second curved portion 310c2 may include a portion (or a second half portion) between the center portion 310b and the second end 310a2.

The first light emitting device ED1 disposed at each of the plurality of sub-pixels SP may be disposed (or aligned) to overlap the first curved portion 310c1 of a corresponding optical element 310. The first light emitting device ED1 may be disposed (or aligned) to overlap the first curved portion 310c1 of the curved portion 310c. The first light emitting device ED1 may be disposed (or aligned) below the first curved portion 310c1 of the curved portion 310c.

In one or more embodiments, a center of the first light emitting device ED1 may be aligned with a center 310d1 of the first curved portion 310c1. In one or more other embodiments, the center of the first light emitting device ED1 may be aligned between the first end 310a1 and the center 310d1 of the first curved portion 310c1. Accordingly, light emitted by the light emission of the first light emitting device ED1 disposed at each of the plurality of sub-pixels SP may be emitted in a first viewing angle direction by the curved portion 310c. The light emitted from the first light emitting device ED1 may be emitted only in a left viewing angle direction.

The second light emitting device ED2 disposed at each of the plurality of sub-pixels SP may be disposed (or aligned) to overlap the second curved portion 310c2 of a corresponding optical element 310. For example, the second light emitting device ED2 may be disposed (or aligned) to overlap the second curved portion 310c2 of the curved portion 310c. For example, the second light emitting device ED2 may be disposed (or aligned) below the second curved portion 310c2 of the curved portion 310c.

In one or more embodiments, a center of the second light emitting device ED2 may be aligned with a center 310d2 of the second curved portion 310c2. In one or more other embodiments, the center of the second light emitting device ED2 may be aligned between the second end 310a2 and the center 310d2 of the second curved portion 310c2. Accordingly, light emitted by the light emission of the second light emitting device ED2 disposed at each of the plurality of sub-pixels SP may be emitted in a second viewing angle direction by the curved portion 310c. The light emitted from the second light emitting device ED2 may be emitted only in a right viewing angle direction.

The optical member 300 may further include a protective layer 330 covering the plurality of optical elements 310. The protective layer 330 may be configured to cover each of the plurality of optical elements 310 and provide a flat surface on the plurality of optical elements 310.

The optical member 300 may be covered by the opposite substrate 200. The opposite substrate 200 may be attached (or coupled) to the protective layer 330 of the optical member 300 by an adhesive member. Accordingly, the optical member 300 may be disposed between the substrate 100 and the opposite substrate 200, and thus, may be embedded inside the display panel 10, but is not limited thereto. For example, the optical member 300 according to one or more other embodiments may not be embedded inside the display panel 10 but may be disposed outside the display panel 10. For example, the optical member 300 may be attached to the opposite substrate 200 by an adhesive member.

An arrangement position of the optical member 300 according to one or more embodiments of the present disclosure may be embedded inside the display panel 10 or disposed outside the display panel 10 based on a physical distance (or an optical distance) between the light emitting part EP and the optical element 310.

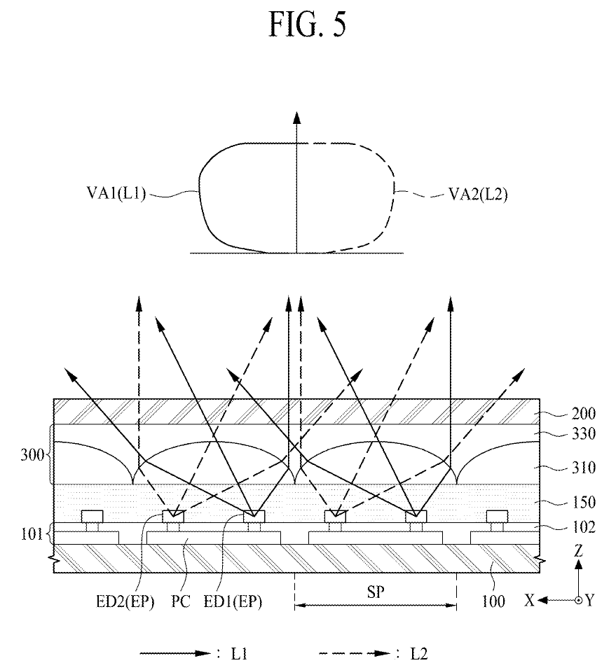

FIG. 4 is a view illustrating a method of driving a sub-pixel according to a first image mode of a light emitting display apparatus according to one or more embodiments of the present disclosure. FIG. 5 is a view illustrating a path of light emitted from a light emitting part according to the method of driving a sub-pixel illustrated in FIG. 4.

Referring to FIGS. 4 and 5, in the light emitting display apparatus according to one or more embodiments of the present disclosure, the data signal Vdata, the scan signal SS, and the first and second device selection signals DSS1 and DSS2 having the first logic state (or the gate-off voltage) based on the first image mode may be supplied to the pixel circuit PC of the sub-pixel SP.

The third thin-film transistor T3 of the pixel circuit PC may be turned-off by the first device selection signal DSS1 of the first logic state, and the fourth thin-film transistor T4 may be turned-off by the first device selection signal DSS1 of the first logic state. In addition, the first thin-film transistor T1 of the pixel circuit PC may supply a data current corresponding to the data signal Vdata, which is supplied through the second thin-film transistor T2 turned-on by the scan signal SS, to the light emitting part EP, and the first and second light emitting devices ED1 and ED2 of the light emitting part EP may simultaneously emit light by a same data current supplied from the first thin-film transistor T1. Accordingly, light L1 emitted by the light emission of the first light emitting device ED1 may be emitted only in a first viewing angle area VA1 (or a left viewing angle direction) according to a light guide of the optical element 310, and light L2 emitted by the light emission of the second light emitting device ED2 may be emitted only in a second viewing angle area VA2 (or a right viewing angle direction) according to the light guide of the optical element 310.

Therefore, the display panel 10 may simultaneously display a dual-view image by the light L1 emitted according to the light emission of the first light emitting device ED1 and the light L2 emitted according to the light emission of the second light emitting device ED2 based on the first image mode. The display panel 10 based on the first image mode may simultaneously display dual-view images that may be viewed simultaneously without a decrease in resolution through the simultaneous light emission of the first and second light emitting devices ED1 and ED2 disposed at each of the plurality of sub-pixels SP. For example, a first viewer located on a left side of the display panel 10 may view an image through the light L1 emitted only in the first viewing angle area VA1 (or the left viewing angle direction), and a second viewer located on a right side of the display panel 10 may view an image through the light L2 emitted only in the second viewing angle area VA2 (or the right viewing angle direction). For example, the dual-view image may be an entertainment image or a media image, but is not limited thereto.

According to one or more embodiments, when the light emitting display apparatus according to one or more embodiments of the present disclosure is a vehicle display disposed at a middle portion of a dashboard of a vehicular apparatus (or a vehicle), a driver in a driver’s seat and a passenger in a front passenger seat may simultaneously view the same image through light L1 emitted only in the first viewing angle area VA1 (or a left viewing angle direction) and light L2 emitted only in the second viewing angle area VA2 (or a right viewing angle direction). Accordingly, the light emitting display apparatus according to one or more embodiments of the present disclosure may display a dual-view image on the display panel 10 without a decrease in resolution based on the first image mode, and thus, the driver and the passenger located on the left and right sides of the display panel 10 may simultaneously view the image displayed on the display panel 10 without a decrease in resolution.

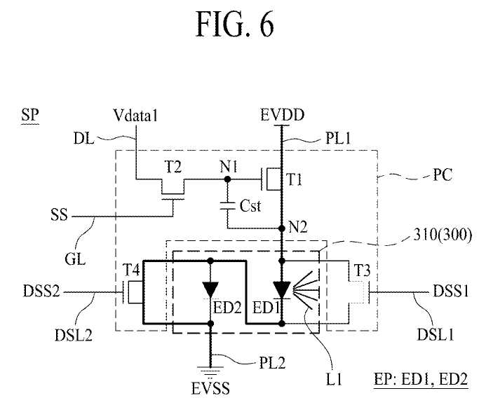

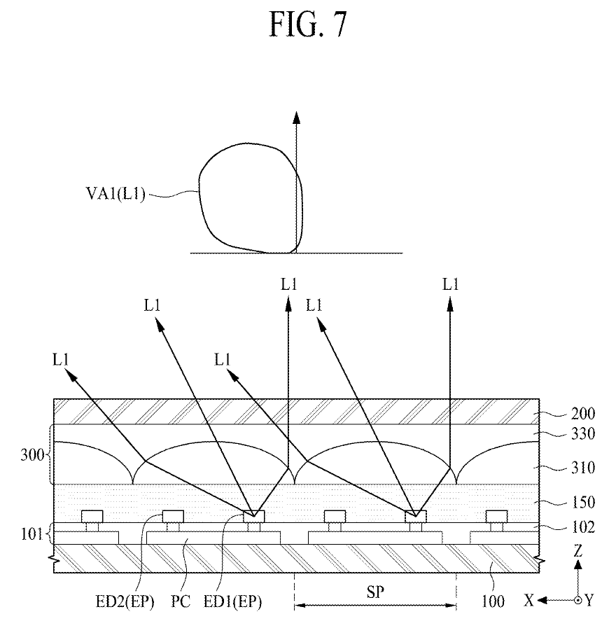

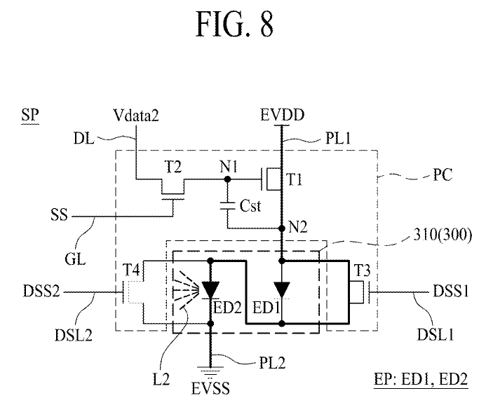

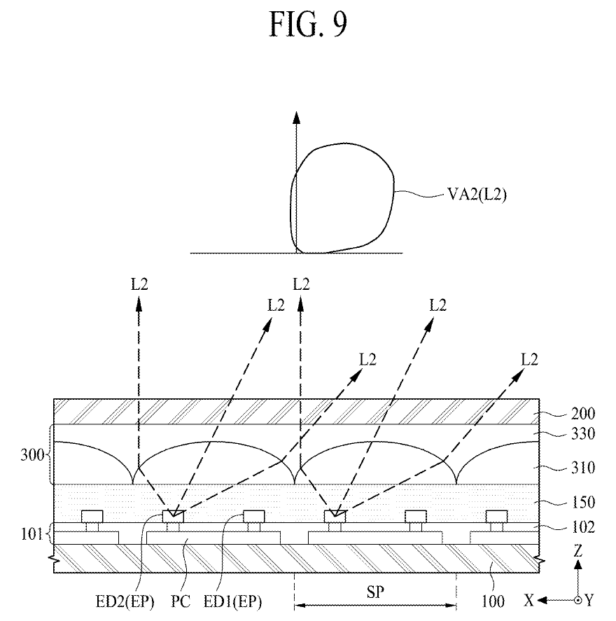

FIG. 6 is a view illustrating a method of driving a sub-pixel for an N-th frame period in a second image mode of a light emitting display apparatus according to one or more embodiments of the present disclosure. FIG. 7 is a view illustrating a path of light emitted from a light emitting part according to the method of driving a sub-pixel illustrated in FIG. 6. FIG. 8 is a view illustrating a method of driving a sub-pixel for an (N+1)-th frame period in a second image mode of a light emitting display apparatus according to one or more embodiments of the present disclosure. FIG. 9 is a view illustrating a path of light emitted from a light emitting part according to the method of driving a sub-pixel illustrated in FIG. 8.

Referring to FIGS. 6 and 7, in the light emitting display apparatus according to one or more embodiments of the present disclosure, a data signal Vdata, a scan signal SS, a first device selection signal DSS1 having a first logic state (or a gate-off voltage), and a second device selection signal DSS2 having a second logic state (or a gate-on voltage) based on an N-th frame period of the second image mode may be supplied to the pixel circuit PC of the sub-pixel SP.

In the N-th frame period of the second image mode, the third thin-film transistor T3 of the pixel circuit PC is turned-off by the first device selection signal DSS1 of the first logic state, and the fourth thin-film transistor T4 is turned-on by the second device selection signal DSS2 of the second logic state. In addition, the first thin-film transistor T1 of the pixel circuit PC supplies a data current corresponding to a first data signal Vdata1, which is supplied through the second thin-film transistor T2 turned-on by the scan signal SS, to the light emitting part EP, and only the first light emitting device ED1 among the first and second light emitting devices ED1 and ED2 of the light emitting part EP may emit light based on the data current (or a first data current) supplied from the first thin-film transistor T1. Accordingly, light L1 emitted by the light emission of the first light emitting device ED1 may be emitted only in the first viewing angle area VA1 (or the left viewing angle direction) based on a light guide of the optical element 310.

Therefore, the display panel 10 may display a first image by the light L1 emitted according to the light emission of the first light emitting device ED1 during the N-th frame period of the second image mode. During the N-th frame period of the second image mode, the display panel 10 may display a first single-view image through independent light emission (or individual light emission) of the first light emitting device ED1 disposed at each of the plurality of sub-pixels SP. For example, a first viewer located on the left side of the display panel 10 may view only the first single-view image through the light L1 emitted only in the first viewing angle area VA1 (or the left viewing angle direction) during the N-th frame period. For example, a driver in a driver’s seat of a vehicular apparatus may individually view only the first image through the light L1 emitted only in the first viewing angle area VA1 (or the left viewing angle direction). For example, the first image may be a vehicle navigation image.

Referring to FIGS. 8 and 9, in the light emitting display apparatus according to one or more embodiments of the present disclosure, a data signal Vdata, a scan signal SS, the first device selection signal DSS1 having the second logic state, and the second device selection signal DSS2 having the first logic state based on an (N+1)-th frame period of the second image mode may be supplied to the pixel circuit PC of the sub-pixel SP.

In the (N+1)-th frame period of the second image mode, the third thin-film transistor T3 of the pixel circuit PC is turned-on by the first device selection signal DSS1 of the second logic state, and the fourth thin-film transistor T4 is turned-off by the second device selection signal DSS2 of the first logic state. In addition, the first thin-film transistor T1 of the pixel circuit PC supplies a data current corresponding to a second data signal Vdata2, which is supplied through the second thin-film transistor T2 turned-on by the scan signal SS, to the light emitting part EP, and only the second light emitting device ED2 among the first and second light emitting devices ED1 and ED2 of the light emitting part EP may emit light based on the data current (or a second data current) supplied from the first thin-film transistor T1. Accordingly, light L2 emitted from the second light emitting device ED2 may be emitted only in the second viewing angle area VA2 (or the right viewing angle direction) based on the light guide of the optical element 310.

Therefore, the display panel 10 may display a second image by the light L2 emitted according to the light emission of the second light emitting device ED2 during the (N+1)-th frame period of the second image mode. During the (N+1)-th frame period of the second image mode, the display panel 10 may display a second single-view image through independent light emission (or individual light emission) of the second light emitting device ED2 disposed at each of the plurality of sub-pixels SP. For example, a second viewer located on the right side of the display panel 10 may view only the second single-view image through the light L2 emitted only in the second viewing angle area VA2 (or the right viewing angle direction) during the (N+1)-th frame period. For example, a passenger in a front passenger seat of the vehicular apparatus may individually view only the second image through the light L2 emitted only in the second viewing angle area VA2 (or the right viewing angle direction). For example, the second image may be an entertainment image or a media image different from the first image, but is not limited thereto.

The driver of the vehicular apparatus may view only the first single-view image by the light guide of the optical member 300 while driving and cannot view the second single-view image that distracts driving, so the driver may concentrate on driving.

As described above, the first and second light emitting devices ED1 and ED2 disposed at each of the plurality of sub-pixels SP may alternately emit light in units of a frame period by different data currents based on the second image mode, and the light emitting display apparatus may alternately display different first and second single-view images in units of a frame period. Accordingly, the light emitting display apparatus according to one or more embodiments of the present disclosure may provide different single-view images to the driver and the passenger located on the left and right sides of the display panel 10 based on the second image mode. For example, the driver in the driver’s seat and the passenger in the front passenger seat may individually view different images displayed on the display panel 10 based on the second image mode.

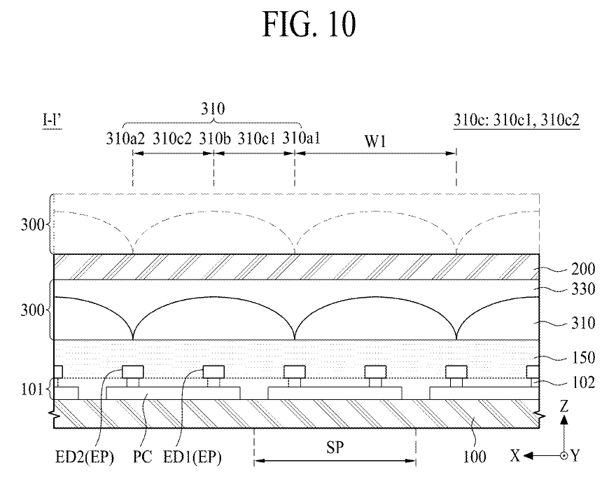

FIG. 10 is another cross-sectional view taken along line I-I’ illustrated in FIG. 1. FIG. 10 is a view for explaining an optical member according to one or more other embodiments of the present disclosure. In the following description, therefore, the optical member and relevant elements will be only described, the other elements may be referred to by same reference numerals as FIGS. 1- 3, and thus, their repetitive descriptions are omitted. Therefore, the descriptions of FIGS. 1-3 may be included in the descriptions of FIG. 10.

Referring to FIG. 10, the optical member 300 according to one or more other embodiments of the present disclosure may include a plurality of optical elements 310. The plurality of optical elements 310 may be substantially the same as the optical elements described above with reference to FIG. 3, and thus, their repetitive descriptions are omitted.

The first light emitting device ED1 disposed at each of the plurality of sub-pixels SP may be disposed (or aligned) to overlap the center portion 310b of a corresponding optical element (or lenticular lens) 310. For example, the first light emitting device ED1 may be disposed (or aligned) below the center portion 310b of the corresponding optical element 310.

In one or more embodiments, a center of the first light emitting device ED1 may be aligned with the center portion 310b of the corresponding optical element 310. For example, the center of the first light emitting device ED1 may be aligned below the center portion 310b of the corresponding optical element 310. Accordingly, light emitted by the light emission of the first light emitting device ED1 disposed at each of the plurality of sub-pixels SP may be emitted in a third viewing angle direction by the curved portion 310c (i.e., both the first curved portion 310c1 and the second curved portion 310c2) of the corresponding optical element 310. For example, the light emitted by the light emission of the first light emitting device ED1 may be emitted only in a front viewing angle direction.

The second light emitting device ED2 disposed at each of the plurality of sub-pixels SP may be disposed (or aligned) to overlap the second end 310a2 of the corresponding optical element (or lenticular lens) 310. For example, a center of the second light emitting device ED2 may be aligned below the second end 310a2 of the corresponding optical element 310. The second light emitting device ED2 may be disposed (or aligned) to overlap a portion (or a boundary portion) between the plurality of optical elements 310. The second light emitting device ED2 may be disposed (or aligned) below a portion (or a boundary portion) between two adjacent optical elements 310 among the plurality of optical elements 310.

The center of the second light emitting device ED2 may be aligned with the second end 310a2 of the corresponding optical element 310. The center of the second light emitting device ED2 may be aligned below the second end 310a2 of the corresponding optical element 310. The center of the second light emitting device ED2 may be aligned with a portion (or a boundary portion) between two adjacent optical elements 310. Accordingly, light emitted by the light emission of the second light emitting device ED2 disposed at each of the plurality of sub-pixels SP may be emitted in a fourth viewing angle direction by the curved portion 310c of the corresponding optical element 310. For example, the light emitted by the light emission of the second light emitting device ED2 may be emitted only in a side viewing angle direction (or left and right viewing angles).

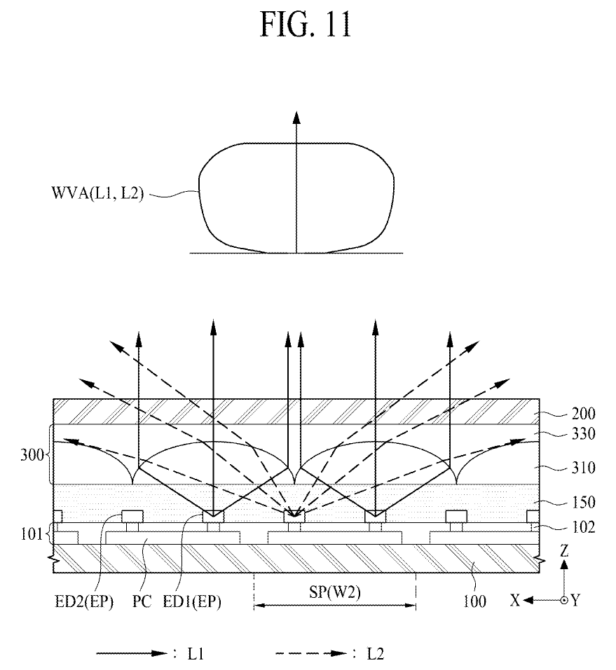

FIG. 11 is a view illustrating a path of light emitted from a light emitting part according to the method of driving a sub-pixel illustrated in FIG. 4.

Referring to FIGS. 4 and 11, in the light emitting display apparatus according to one or more embodiments of the present disclosure, a data signal Vdata, a scan signal SS, and first and second device selection signals DSS1 and DSS2 having a first logic state (or a gate-off voltage) based on a first viewing angle mode (or a wide viewing angle mode) are supplied to the pixel circuit PC of the sub-pixel SP.

The third thin-film transistor T3 of the pixel circuit PC is turned-off by the first device selection signal DSS1 of the first logic state, and the fourth thin-film transistor T4 is turned-off by the first device selection signal DSS1 of the first logic state. In addition, the first thin-film transistor T1 of the pixel circuit PC supplies a data current corresponding to the data signal Vdata, which is supplied through the second thin-film transistor T2 turned-on by the scan signal SS, to the light emitting part EP, and the first and second light emitting devices ED1 and ED2 of the light emitting part EP may simultaneously emit light by the same data current supplied from the first thin-film transistor T1. Accordingly, light L1 emitted by the light emission of the first light emitting device ED1 is emitted only in a third viewing angle area (or a front viewing angle direction) based on a light guide of the optical element 310, and light L2 emitted from the second light emitting device ED2 may be emitted only in a fourth viewing angle area (or a side viewing angle direction) based on the light guide of the optical element 310.

Therefore, in the first viewing angle mode, the display panel 10 may display a general view image of a wide viewing angle (WVA) by the light L1 emitted according to the light emission of the first light emitting device ED1 and the light L2 emitted according to the light emission of the second light emitting device ED2. For example, the display panel 10 according to the first viewing angle mode may display a general view image of a wide viewing angle (WVA) without a decrease in resolution through the simultaneous light emission of the first light emitting device ED1 and the second light emitting device ED2 disposed at each of the plurality of sub-pixels SP. For example, the general view image may be an entertainment image or a media image, but is not limited thereto.

According to one or more embodiments, a driver in a driver’s seat and a passenger in a front passenger seat may simultaneously view the general view image of the wide viewing angle (WVA) through light L1 emitted according to light emission of the first light emitting device ED1 and light L2 emitted according to light emission of the second light emitting device ED2 based on the first viewing angle mode. Accordingly, the light emitting display apparatus according to one or more embodiments of the present disclosure may display the general view image on the display panel 10 without a decrease in resolution based on the first viewing angle mode, and thus, the driver and the passenger located on the left and right sides of the display panel 10 may simultaneously view the image displayed on the display panel 10 without a decrease in resolution.

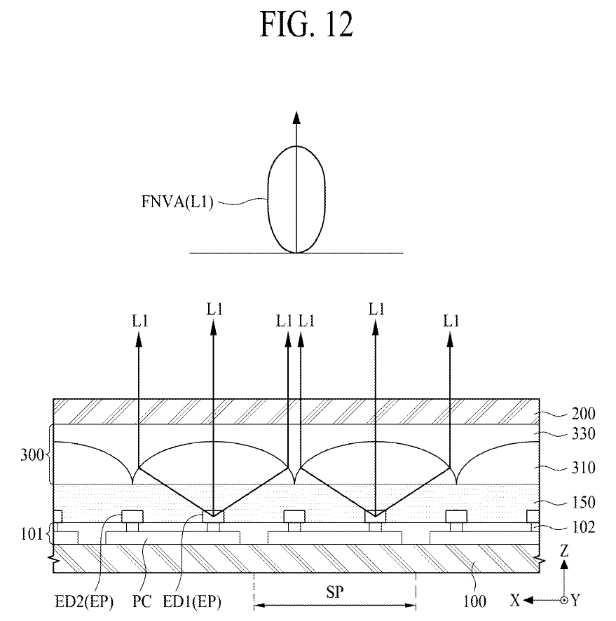

FIG. 12 is a view illustrating a path of light emitted from a light emitting part according to the method of driving a sub-pixel illustrated in FIG. 6.

Referring to FIGS. 6 and 12, in the light emitting display apparatus according to one or more embodiments of the present disclosure, a data signal Vdata, a scan signal SS, a first device selection signal DSS1 having a first logic state (or a gate-off voltage), and a second device selection signal DSS2 having a second logic state (or a gate-on voltage) based on a second viewing angle mode (or a narrow viewing angle mode or a privacy mode (or a personal security mode)) are supplied to the pixel circuit PC of the sub-pixel SP.

In the second viewing angle mode, the third thin-film transistor T3 of the pixel circuit PC is turned-off by the first device selection signal DSS1 of the first logic state, and the fourth thin-film transistor T4 is turned-on by the second device selection signal DSS2 of the second logic state. In addition, the first thin-film transistor T1 of the pixel circuit PC supplies a data current corresponding to a first data signal Vdata1, which is supplied through the second thin-film transistor T2 turned-on by the scan signal SS, to the light emitting part EP, and only the first light emitting device ED1 among the first and second light emitting devices ED1 and ED2 of the light emitting part EP may emit light according to the data current supplied from the first thin-film transistor T1. Accordingly, light L1 emitted by the light emission of the first light emitting device ED1 may be emitted only in a third viewing angle area FNVA based on a light guide of the optical element 310. The first data signal Vdata1 may correspond to a personal security image (or an individual image or a separate image) that is different from an image displayed in the first viewing angle mode described above with reference to FIGS. 4 and 11. For example, the third viewing angle area FNVA may be a front narrow viewing angle area, a front viewing angle direction, or a front narrow viewing angle direction.

In the second viewing angle mode, the second light emitting device ED2 may maintain a non-emission state due to the turn-on of the fourth thin-film transistor T4.

Therefore, in the second viewing angle mode, the display panel 10 may display a personal security image of a front narrow viewing angle by the light L1 emitted according to the light emission of the first light emitting device ED1. For example, in the second viewing angle mode, the display panel 10 may display the personal security image of the front narrow viewing angle by the light L1 emitted according to independent light emission (or individual light emission) of the first light emitting device ED1 disposed at each of the plurality of sub-pixels SP. For example, a front viewer located in a front of the display panel 10 may view only the personal security image through the light L1 emitted only in the third viewing angle area FNVA, and a side viewer located on the left or right side of the display panel 10 cannot view the personal security image, and thus, security for the personal security image displayed on the display panel 10 may be improved. For example, the personal security image may be a personal image, an entertainment image, or a media image, but is not limited thereto.

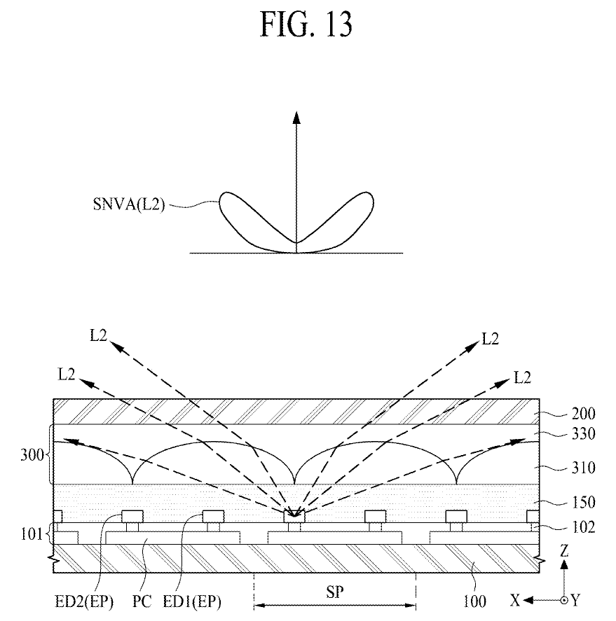

FIG. 13 is a view illustrating a path of light emitted from a light emitting part according to the method of driving a sub-pixel illustrated in FIG. 8.

First, in the second viewing angle mode of the light emitting display apparatus according to one or more embodiments of the present disclosure, a plurality of sub-pixels SP may be driven with an N-th frame period and an (N+1)-th frame period.

In the second viewing angle mode, in the N-th frame period of the second viewing angle mode, as described above with reference to FIGS. 6 and 12, only the first light emitting device ED1 among the first and second light emitting devices ED1 and ED2 of the light emitting part EP may emit light based on the data current supplied from the first thin-film transistor T1. Accordingly, in the N-th frame period of the second viewing angle mode, the display panel 10 may display the personal security image of the front narrow viewing angle by light L1 emitted in the third viewing angle area FNVA according to independent light emission (or individual light emission) of the first light emitting device ED1 disposed at each of the plurality of sub-pixels SP.

Referring to FIGS. 8 and 13, in the light emitting display apparatus according to one or more embodiments of the present disclosure, a data signal Vdata, a scan signal SS, the first device selection signal DSS1 having the second logic state, and the second device selection signal DSS2 having the first logic state based on the (N+1)-th frame period of the second viewing angle mode are supplied to the pixel circuit PC of the sub-pixel SP.

In the (N+1)-th frame period of the second viewing angle mode, the third thin-film transistor T3 of the pixel circuit PC is turned-on by the first device selection signal DSS1 of the second logic state, and the fourth thin-film transistor T4 is turned-off by the second device selection signal DSS2 of the first logic state. In addition, the first thin-film transistor T1 of the pixel circuit PC supplies a data current corresponding to a second data signal Vdata2, which is supplied through the second thin-film transistor T2 turned-on by the scan signal SS, to the light emitting part EP, and only the second light emitting device ED2 among the first and second light emitting devices ED1 and ED2 of the light emitting part EP may emit light based on the data current supplied from the first thin-film transistor T1. Accordingly, light L2 emitted from the second light emitting device ED2 may be emitted only in a fourth viewing angle area (or a side viewing angle direction) SNVA based on the light guide of the optical element 310.

Therefore, the display panel 10 may display a personal non-security image by the light L2 emitted according to the light emission of the second light emitting device ED2 during the (N+1)-th frame period of the second image mode. During the (N+1)-th frame period of the second image mode, the display panel 10 may display the personal non-security image of a side narrow viewing angle by the light L2 emitted according to independent light emission (or individual light emission) of the second light emitting device ED2 disposed at each of the plurality of sub-pixels SP. For example, a side viewer located on the left or right side of the display panel 10 may view only the personal non-security image through the light L2 emitted only in the fourth viewing angle area SNVA, and the side viewer cannot view the personal security image by the light L1 emitted only in the third viewing angle area FNVA, and thus, the security for the personal security image displayed on the display panel 10 may be improved. For example, the personal non-security image may be an entertainment image or a media image different from the personal security image, but is not limited thereto.

As described above, the first and second light emitting devices ED1 and ED2 disposed at each of the plurality of sub-pixels SP may alternately emit light in units of a frame period by different data currents based on the second viewing angle mode, and the light emitting display apparatus may alternately display different personal security images and personal non-security images in units of a frame period. Accordingly, the light emitting display apparatus according to one or more embodiments of the present disclosure may provide only the personal security image to the front viewer located in the front of the display panel 10 based on the second viewing angle mode, and simultaneously provide only the personal non-security image to the side viewer located on the side of the display panel 10. Therefore, in the light emitting display apparatus according to one or more embodiments of the present disclosure, security for the personal security image provided to the front viewer may be improved.

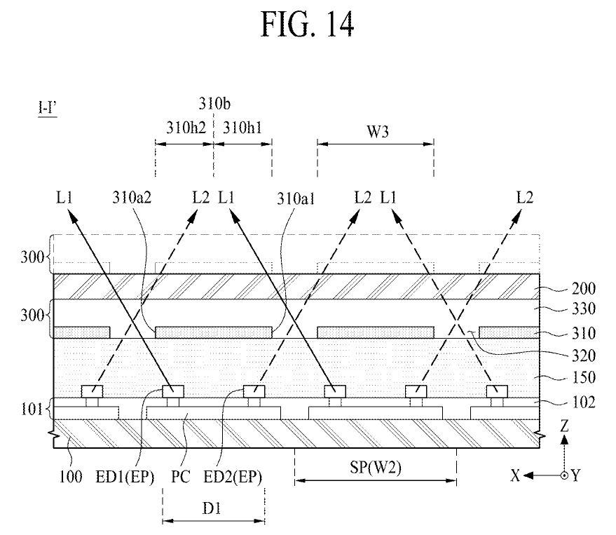

FIG. 14 is another cross-sectional view taken along line I-I’ illustrated in FIG. 1. FIG. 14 is a view for explaining one or more embodiments in which an optical member is modified in the light emitting display apparatus described above with reference to FIGS. 1 - 9. In the following description, therefore, the optical member and relevant elements will be only described, the other elements may be referred to by same reference numerals as FIGS. 1 - 9, and thus, their repetitive descriptions are omitted. Therefore, the descriptions of FIGS. 1 - 9 may be included in the descriptions of FIG. 14.

Referring to FIG. 14, the optical member 300 according to one or more other embodiments of the present disclosure may include a plurality of optical elements 310.

Each of the plurality of optical elements 310 may include a light blocking pattern (or a barrier pattern). For example, the optical member 300 having the plurality of optical elements 310 may be a light blocking member or a barrier film. The light blocking pattern of each of the plurality of optical elements 310 may be made of a material capable of blocking light incident from each of the first and second light emitting devices ED1 and ED2. For example, the light blocking pattern may be made of a black material, polyamide, or a light absorbing material.

The light blocking pattern of each of the plurality of optical elements 310 may be disposed (or aligned) to overlap both the first and second light emitting devices ED1 and ED2 which are disposed at a corresponding sub-pixel SP among the plurality of sub-pixels SP. Both the first and second light emitting devices ED1 and ED2 may be disposed below one light blocking pattern. In a plan view, both the first and second light emitting devices ED1 and ED2 may be covered by one light blocking pattern.

The light blocking pattern of each of the plurality of optical elements 310 may include a rectangular shape (or a line shape) having a width D1 and a length. For example, the light blocking pattern of each of the plurality of optical elements 310 may have a plate shape having a width D1 and a length.

Each of the plurality of optical elements (or light blocking patterns) 310 may include a first end 310a1, a second end 310a2, and a center portion 310b.

The first end 310a1 may be one end (or one side end) of each of the plurality of optical elements (or light blocking patterns) 310. The second end 310a2 may be the other end (or the other side end) of each of the plurality of optical elements (or light blocking patterns) 310 which is opposite to the first end 310a1. The first end 310a1 and the second end 310a2 may be parallel to each other and may be parallel to a data line.

The center portion 310b may include a middle portion between the first end 310a1 and the second end 310a2. The first end 310a1 and the second end 310a2 may be parallel to each other with the center portion 310b therebetween. For example, each of the plurality of optical elements (or light blocking patterns) 310 may have a symmetrical structure (or a left-right symmetrical structure) with respect to the center portion 310b.

Each of the plurality of optical elements (or light blocking patterns) 310 may include a first portion (or a first half portion) 310h1 and a second portion (or a second half portion) 310h2.

The first portion 310h1 may include a portion between the center portion 310b and the first end 310a1. The second portion 310h2 may include a portion between the center portion 310b and the second end 310a2.

A width W3 of one light blocking pattern may be greater than a maximum length D1 between the first and second light emitting devices ED1 and ED2. The width W3 of the light blocking pattern may be smaller than a width W2 of one sub-pixel SP. For example, the width W3 of the light blocking pattern may be smaller than a pitch of the plurality of sub-pixels SP.

The optical member 300 may further include a plurality of openings 320 disposed between the plurality of optical elements 310. Each of the plurality of openings 320 may be disposed (or configured) between two adjacent optical elements (or light blocking patterns) 310 among the plurality of optical elements (or light blocking patterns) 310. A center (or center portion) of each of the plurality of openings 320 may be disposed (or aligned) at a center (or center portion) between two adjacent sub-pixels SP.

The first light emitting device ED1 disposed at each of the plurality of sub-pixels SP may be disposed (or aligned) to overlap the second half portion 310h2 of a corresponding optical element 310. The first light emitting device ED1 may be disposed (or aligned) below the second half portion 310h2 of the corresponding optical element 310. An outer wall of the first light emitting device ED1 may overlap a second rear edge portion of the corresponding optical element 310 corresponding to the second half portion 310h2 of the corresponding optical element 310. The first light emitting device ED1 may be disposed below the second rear edge portion of the corresponding optical element 310.

Light emitted from the first light emitting device ED1 disposed at each of the plurality of sub-pixels SP may pass through a relatively adjacent opening 320 among the plurality of openings 320 and be emitted in a first viewing angle direction. The light emitted from the first light emitting device ED1 may be emitted only in a left viewing angle direction. Since the light emitted from the first light emitting device ED1 may be a same as the light emitted from the first light emitting device ED1 described above with reference to FIGS. 1 - 9, and thus, repeated descriptions thereof are omitted.

The second light emitting device ED2 disposed at each of the plurality of sub-pixels SP may be disposed (or aligned) to overlap the first half portion 310h1 of the corresponding optical element 310. The second light emitting device ED2 may be disposed (or aligned) below the first half portion 310h1 of the corresponding optical element 310. An outer wall of the second light emitting device ED2 may overlap a first rear edge portion of the corresponding optical element 310 corresponding to the first half portion 310h1 of the corresponding optical element 310. The second light emitting device ED2 may be disposed below the first rear edge portion of the corresponding optical element 310.

Light emitted from the second light emitting device ED2 disposed at each of the plurality of sub-pixels SP may pass through a relatively adjacent opening 320 among the plurality of openings 320 and be emitted in a second viewing angle direction. Light emitted from the second light emitting device ED2 may be emitted only in a right viewing angle direction. Since the light emitted from the second light emitting device ED2 may be a same as the light emitted from the second light emitting device ED2 described above with reference to FIGS. 1- 9, and thus, repeated descriptions thereof are omitted.

The optical member 300 may further include a protective layer 330 covering the plurality of optical elements (or light blocking patterns) 310 and the plurality of openings 320. The protective layer 330 may be configured to cover each of the plurality of optical elements 310 and configured to provide a flat surface on the plurality of optical elements (or light blocking patterns) 310 and the plurality of openings 320.

The optical member 300 according to one or more embodiments may be covered by an opposite substrate 200. For example, the opposite substrate 200 may be attached (or coupled) to the protective layer 330 of the optical member 300 by using an adhesive member. For example, an arrangement position of the optical member 300 may be embedded in the display panel 10 or disposed outside the display panel 10 based on a physical distance (or an optical distance) between the light emitting part EP and the optical element 310.

As described above, in the light emitting display apparatus including the optical member 300 having the light blocking pattern according to one or more other embodiments of the present disclosure, a path of light emitted from the light emitting part EP based on a method of driving the sub-pixel are a same as described above with reference to FIGS. 4 - 9, and thus, repeated descriptions thereof are omitted. Therefore, the light emitting display apparatus described above with reference to FIG. 14 may have same effects as the light emitting display apparatus described above with reference to FIGS. 4- 9.

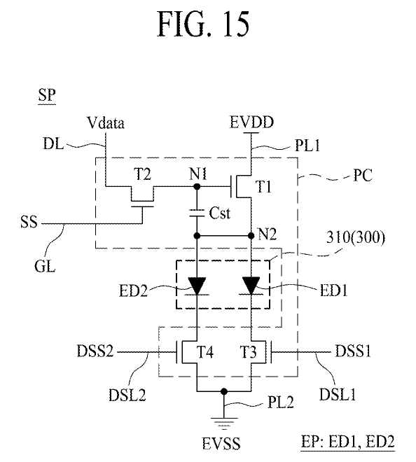

FIG. 15 is an equivalent circuit diagram illustrating one sub-pixel illustrated in FIG. 1. FIG. 15 is a view in which the first and second light emitting devices described above with reference to FIGS. 2- 14 are changed to a parallel structure. In the following description, therefore, the parallel structure of the first and second light emitting devices and relevant elements will be only described, the other elements may be referred to by same reference numerals as FIGS. 2 -14, and thus, their repetitive descriptions are omitted. Therefore, the descriptions of FIGS. 2- 14 may be included in the descriptions of FIG. 15.

Referring to FIG. 15, in a sub-pixel SP according to one or more other embodiments of the present disclosure, a first light emitting device ED1 and a second light emitting device ED2 may be electrically connected in parallel.

The first light emitting device ED1 and the second light emitting device ED2 may be electrically connected in parallel between a first thin-film transistor T1 and a second power line PL2. For example, the first light emitting device ED1 and the second light emitting device ED2 may be electrically connected in parallel between a second node N2 connected to the first thin-film transistor T1 and the second power line PL2.

A first electrode of each of the first light emitting device ED1 and the second light emitting device ED2 may be commonly connected to the first thin-film transistor T1. The first electrode of each of the first light emitting device ED1 and the second light emitting device ED2 may be commonly connected to the second node N2 connected to the first thin-film transistor T1. Accordingly, the first light emitting device ED1 and the second light emitting device ED2 may simultaneously receive a data current output from the first thin-film transistor T1.

The third thin-film transistor T3 is turned-on based on a first device selection signal DSS1 and may be configured to block a current flowing to the first light emitting device ED1. The third thin-film transistor T3 may be electrically connected in series between the first light emitting device ED1 and the second power line PL2. Except for that the third thin-film transistor T3 is electrically connected in series between the first light emitting device ED1 and the second power line PL2, the third thin-film transistor T3 is substantially a same as the third thin-film transistor T3 described above with reference to FIGS. 2 - 14, and thus, repeated descriptions thereof are omitted.

The fourth thin-film transistor T4 is turned-on based on a second device selection signal DSS2 and may be configured to block a current flowing to the second light emitting device ED2. The fourth thin-film transistor T4 may be electrically connected in series between the second light emitting device ED2 and the second power line PL. Except for that the fourth thin-film transistor T4 is electrically connected in series between the second light emitting device ED2 and the second power line PL2, the fourth thin-film transistor T4 is substantially a same as the fourth thin-film transistor T4 described above with reference to FIGS. 2- 14, and thus, repeated descriptions thereof are omitted. For example, the sub-pixel SP described above with reference to FIGS. 2 - 14 may be changed to the sub-pixel SP described above with reference to FIG. 15.

As described above, the light emitting display apparatus including the sub-pixel SP described above with reference to FIG. 15 may have same effects as the light emitting display apparatus described above with reference to FIGS. 2-14, and thus, repeated descriptions thereof are omitted.

It will be apparent to those skilled in the art that various modifications and variations can be made in the present disclosure without departing from the spirit or scope of the disclosures. Thus, it is intended that the present disclosure covers the modifications and variations of this disclosure provided that within the scope of the claims and their equivalents.

What is claimed is:

1. A light emitting display apparatus, comprising:
a substrate including a plurality of sub-pixels; and
an optical member disposed on the substrate, the optical member including a plurality of optical elements overlapping each of the plurality of sub-pixels,
wherein each of the plurality of sub-pixels comprises:
a pixel circuit connected to a data line and a gate line; and
a light emitting part including a first light emitting device and a second light emitting device configured to emit light by a data current supplied from the pixel circuit, and
wherein each of the plurality of optical elements is configured to control traveling paths of light emitted from each of the first light emitting device and the second light emitting device in different directions.

2. The light emitting display apparatus of claim 1,
wherein each of the first light emitting device and the second light emitting device is a light emitting diode device or a light emitting diode chip, and
wherein the first light emitting device and the second light emitting device overlap a corresponding one of the plurality of optical elements.

3. The light emitting display apparatus of claim 2,
wherein each of the plurality of optical elements comprises a lenticular lens, and
wherein the lenticular lens comprises:
a first end;
a second end opposite to the first end;
a center portion between the first end and the second end; and
a curved portion between the first end and the second end.

4. The light emitting display apparatus of claim 3,
wherein the curved portion comprises:
a first curved portion between the center portion and the first end; and
a second curved portion between the center portion and the second end,
wherein the first light emitting device is disposed to overlap the first curved portion of the lenticular lens, and
wherein the second light emitting device is disposed to overlap the second curved portion of the lenticular lens.

5. The light emitting display apparatus of claim 4, wherein a center of the first light emitting device is aligned with a center of the first curved portion, and wherein a center of the second light emitting device is aligned with a center of the second curved portion.

6. The light emitting display apparatus of claim 4, wherein, in a first image mode of the light emitting display apparatus, the first light emitting device and the second light emitting device configured in each of the plurality of sub-pixels simultaneously emit light by a same data current, and wherein, in a second image mode of the light emitting display apparatus, the first light emitting device and the second light emitting device alternately emit light in units of a frame period by different data currents.

7. The light emitting display apparatus of claim 3,
wherein the first light emitting device is disposed to overlap the center portion of the lenticular lens, and
wherein the second light emitting device is disposed to overlap the second end of the lenticular lens.

8. The light emitting display apparatus of claim 7,
wherein, in a first mode of the light emitting display apparatus, the first light emitting device and the second light emitting device configured in each of the plurality of sub-pixels simultaneously emit light by a same data current, and
wherein, in a second mode of the light emitting display apparatus, the first light emitting device emits light by the data current and the second light emitting device does not emit light.

9. The light emitting display apparatus of claim 7, wherein, in a first mode of the light emitting display apparatus, the first light emitting device and the second light emitting device configured in each of the plurality of sub-pixels simultaneously emit light by a same data current, and wherein, in a second mode of the light emitting display apparatus, the first light emitting device and the second light emitting device alternately emit light in units of a frame period by different data currents.

10. The light emitting display apparatus of claim 1,
wherein each of the plurality of optical elements comprises a light blocking pattern,
wherein the optical member further comprises a plurality of opening portions disposed between the plurality of optical elements,
wherein the light blocking pattern of each of the plurality of optical elements overlaps both the first light emitting device and the second light emitting device disposed in each of the plurality of sub-pixels,
wherein, in a first mode of the light emitting display apparatus, the first light emitting device and the second light emitting device configured in each of the plurality of sub-pixels simultaneously emit light by a same data current ,
wherein, in a second mode of the light emitting display apparatus, the first light emitting device and the second light emitting device alternately emit light in units of a frame period by different data currents, and
wherein light generated from each of the first light emitting device and the second light emitting device is emitted through the plurality of opening portions.

11. The light emitting display apparatus of claim 1, wherein the pixel circuit comprises:
a first thin-film transistor connected to a first power line, a first node, and a second node, the first thin-film transistor configured to control a current flowing to the first power line and the second node based on a voltage of the first node;
a second thin-film transistor turned-on based on a scan signal applied from the gate line and configured to be electrically connected between the data line and the first node;
a capacitor configured to be electrically connected between the first node and the second node;
a third thin-film transistor turned-on based on a first device selection signal and configured to block a current flowing to the first light emitting device; and
a fourth thin-film transistor turned-on based on a second device selection signal and configured to block a current flowing to the second light emitting device,
wherein the first light emitting device and the second light emitting device are electrically connected in series or electrically connected in parallel between the second node and a second power line.

12. The light emitting display apparatus of claim 11, wherein:
the third thin-film transistor is electrically connected in parallel with the first light emitting device, and
the fourth thin-film transistor is electrically connected in parallel with the second light emitting device.
